(19) United States
(12) Patent Application Publication
(10) Pub. No.: US 2001/0005630 A1
(43) Pub. Date: Jun. 28, 2001

(54) Method of filling gap by use of high density plasma oxide film and deposition apparatus therefor

(75) Inventors: Sun-Rae Kim, Suwon-shi (KR); Soo-Geun Lee, Hwasong-gun (KR); Sun-Hoo Park, Yongin-shi (KR)

Correspondence Address: Eugene M. Lee, The Law Offices of Eugene M. Lee, PLLC, Suite 1200, 2111 Wilson Boulevard, Arlington, VA, 22201, US

(73) Assignee: Samsung Electronics Co., Ltd.

(21) Appl. No.: 09/728,478

(22) Filed: Dec. 4, 2000

(30) Foreign Application Priority Data
Dec. 3, 1999 (KR) 54706/1999

(51) Int. Cl. H01L 21/302

(52) U.S. Cl. 438/689; 438/710; 438/712

(57) ABSTRACT

A semiconductor device fabricating method and apparatus for filling gaps between patterns by use of high density plasma oxide films, wherein, a first high density plasma oxide film is deposited on a semiconductor substrate that has patterns with a gap formed thereon and then etched to a predetermined depth using fluorine ions. A second high density plasma oxide film is deposited on the resultant structure, thereby filling the gap between the patterns.

### PRIORITY

This application claims priority to an application entitled “Method of Filling Gap by Use of High Density Plasma Oxide Film and Deposition Apparatus Therefor” filed in the Korean Industrial Property Office on Dec. 3, 1999 and assigned Serial No. 99-54706, the contents of which are hereby incorporated by reference.

### BACKGROUND OF THE INVENTION

1. Field of the Invention

The present invention relates generally to an apparatus and method for fabricating a semiconductor device and, in particular, to a method of filling a gap by use of a high density plasma oxide film and a deposition apparatus therefor.

2. Description of the Related Art

As pattern design rules have scaled down to 0.2 μm or below due to the increased level of semiconductor device integration, it has become more difficult to fill a gap when an insulator is deposited for electrical device isolation. Therefore, a CVD (Chemical Vapor Deposition) process with excellent gap-filling characteristics is under development, and a high density plasma CVD process has been recently developed in which deposition and sputtering concurrently occur, resulting in good gap-filling characteristics.

FIGS. 1 and 2 are sectional views illustrating a conventional gap filling method using a high-density plasma oxide film.

Referring to FIGS. 1 and 2, a plurality of fine patterns 12 are formed at predetermined intervals on a semiconductor substrate 10. Gaps between the fine patterns 12 are filled by depositing a high density plasma oxide film 14 on the resultant structure. A description will be made of the deposition mechanism of the high density oxide film 14 below.

The high density oxide film 14 is deposited by generating a high density plasma using O₂ and Ar gases as plasma sources. That is, SiO₂ is formed out of SiH₄ and O₂ and deposited on a wafer. Ar and O₂ particles are drawn to the surface of the wafer by applying a RF bias voltage to the back side of the wafer. Then, deposition and sputtering occur concurrently, filling the gaps, as shown in FIG. 2. However, because the gap filling limit is 3:1 in aspect ratio in the conventional high density CVD process, voids (16 in FIG. 2) are produced if the aspect ratio of the gaps is 3:1 or higher.

A bit line contact hole for connecting the drain region of a transistor to a bit line and a buried contact hole for connecting the source region of the transistor to the storage electrode of a capacitor have to be formed 0.1 μm or smaller as a pattern design rule has been no larger than 0.2 μm in an MDL (Merged DRAM & Logic) device with a DRAM cell region and a logic region formed on the same chip. Accordingly, a landing pad is typically formed on each of the source and drain regions of a transistor by so-called self-aligned contact processing (forming a contact hole utilizing steps of peripheral structures).

The self-aligned contact process, however, increases the deposition thickness of the gate of the transistor and narrows the gap between gates. Thus, filling the gap has emerged as a challenging issue. The aspect ratio of a gap is 3:1 or higher in the MDL device because the deposition thickness of a gate is no larger than 0.45 μm and the gap between gates is 0.15 μm or narrower. In view of the gap filling limit of 3:1 in terms of aspect ratio in the conventional high density plasma CVD, the filling of a gap is accompanied by formation of voids. The voids bring about a bridge between bit line landing pads or between capacitor landing pads in a subsequent landing pad deposition step, thereby impeding reliable device operations.

FIG. 3 is a sectional view illustrating a model with voids generated in the gap between fine patterns during deposition of a high density plasma oxide film. Here, ∘ denotes Ar ions, □ denotes a deposited oxide film, and ● denotes a redeposited oxide film. Reference characters (a), (b), and (c) denote a narrow gap area between patterns of a predetermined size, a wide gap area, and an area adjacent to the areas (a) and (b), respectively.

Referring to FIG. 3, a high density oxide film 14 experiences sputtering at its corners by Ar ions. Thus, it has a 45° tilted profile. The high density plasma oxide film 14 is thicker in the wide gap area (b) than in the narrow gap area (a) because the sputtering rate is higher in the narrow gap area (a) than in the wide gap area (b).

Sputtered oxide reaches the sidewalls of the underlying patterns 12 directly or collides with Ar ions and then is redeposited on the sidewalls of the underlying patterns 12. A large amount of oxide is deposited on the bottom of a wide gap in the area (b) and thus the redeposition of the oxide gives rise to no voids. On the other hand, a small amount of oxide is deposited on the bottom of a narrow gap in the area (a) and thus the oxide redeposition generates voids. In the area (c), voids are also generated because a large amount of oxide is sputtered on a wide pattern and a larger amount of oxide is redeposited on the sidewalls of a narrow pattern from the wide pattern.

Therefore, when a gap is filled using a high density plasma oxide film only, it is impossible to fill the gap due to an oxide film redeposited on the sidewalls of a pattern as a pattern design rule has been decrease.

### SUMMARY OF THE INVENTION

It is a feature of an embodiment of the present invention to provide a semiconductor device fabricating method in which a gap can be filled by use of a high density plasma oxide film without formation of voids.

In accordance with one aspect of an embodiment of the present invention, there is provided a semiconductor device fabricating method, wherein a first high density plasma oxide film is deposited on a semiconductor substrate that has patterns with a gap formed thereon and then etched to a predetermined depth using fluorine ions. A second high density plasma oxide film is deposited on the resultant structure, thereby filling the gap between the patterns.

Preferably, the above steps are performed in situ. Preferably, the first high density plasma oxide film is deposited to a thickness sufficient to prevent generation of voids in the gap. Preferably, the first high density plasma oxide film is isotropically etched. Preferably, the fluorine ions are formed in a remote plasma method and injected through an annular pipe with a plurality of holes.

According to another aspect of an embodiment of the present invention, there is provided a semiconductor device fabricating apparatus, wherein, a deposition chamber deposits an oxide film using high density plasma, and an etch chamber etches the high density plasma oxide film using fluorine ions formed in a remote plasma method. Preferably, an annular pipe with a plurality of holes is further provided to inject the fluorine ions into the etch chamber. Preferably, two deposition chambers are used for deposition and the etch chamber is connected between the two deposition chambers.

According to other aspects of further embodiments of the present invention, a semiconductor device formed according to the above inventive methods are also provided.

### BRIEF DESCRIPTION OF THE DRAWINGS

The above and other features and advantages of the various embodiments of the present invention will become more apparent from the following detailed description when taken in conjunction with the accompanying drawings in which:

FIGS. 1 and 2 are sectional views illustrating a conventional gap filling method using a high density plasma oxide film;

FIG. 3 is a sectional view illustrating a model with voids generated in the gap between fine patterns during deposition of a high density plasma oxide film;

FIGS. 4, 5, and 6 are sectional views illustrating a gap filling method using a high density plasma oxide film according to an embodiment of the present invention;

FIG. 7 is a schematic view of a high density plasma CVD apparatus used according to an embodiment of the present invention;

FIG. 8 is a detailed schematic view of an etching chamber shown in FIG. 7;

FIG. 9 is a diagram referred to for describing the structure of the etching chamber shown in FIG. 8; and

FIGS. 10 to 14 are sectional views sequentially illustrating a self-aligned contact process in a semiconductor device to which the gap filling method of an embodiment of the present invention is applied.

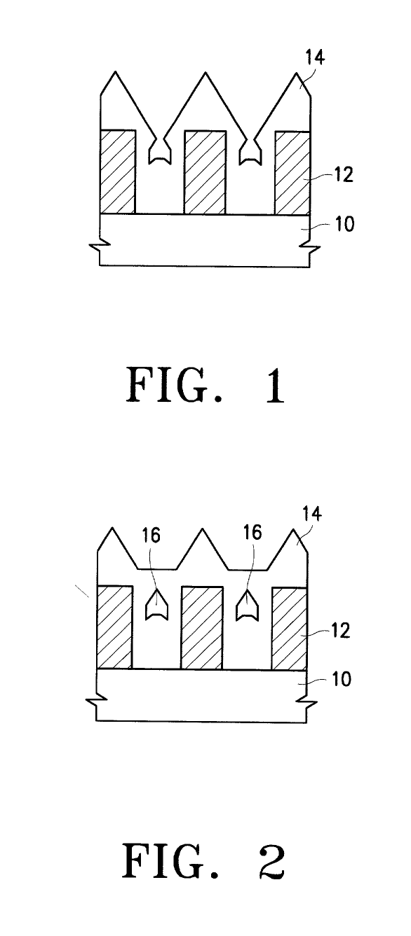

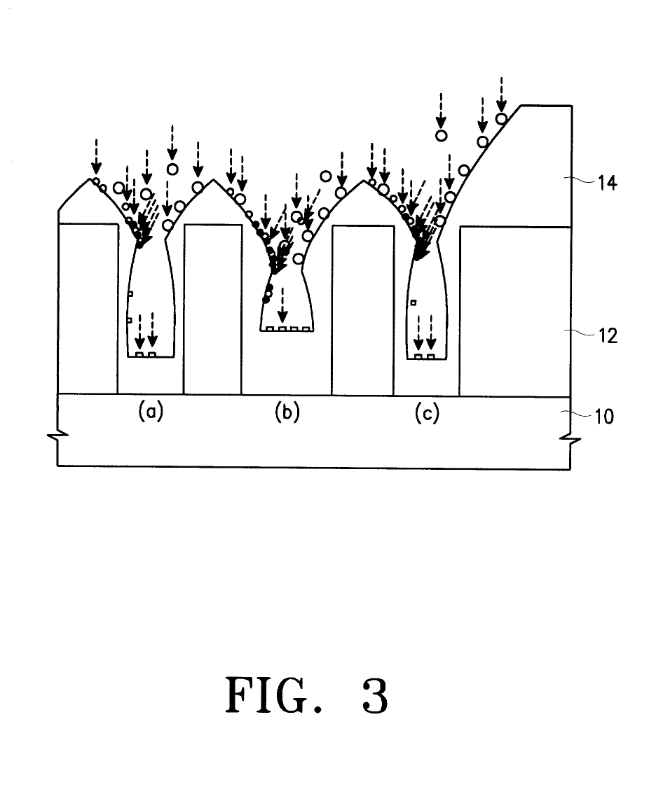

### DETAILED DESCRIPTION OF THE PREFERRED EMBODIMENT

A preferred embodiment of the present invention will be described hereinbelow with reference to the accompanying drawings. In the following description, well-known functions or constructions are not described in detail since they would obscure the invention in unnecessary detail.

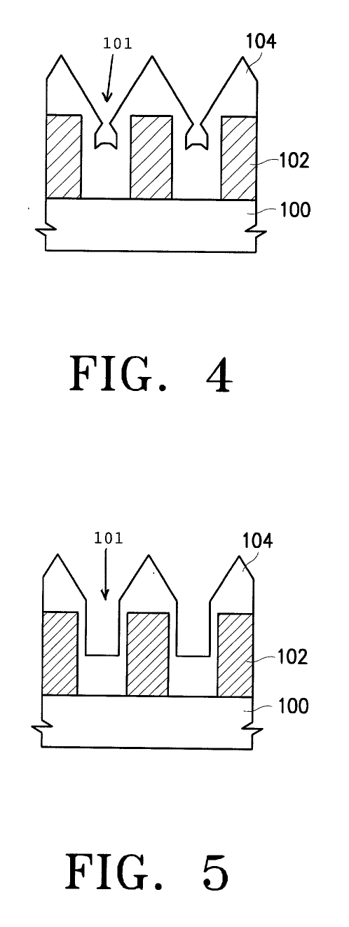

FIGS. 4, 5, and 6 are sectional views illustrating a gap filling method using a high density plasma oxide film according to an embodiment of the present invention and FIG. 7 is a schematic view of a high density plasma CVD apparatus for use according to an embodiment of the present invention.

Referring to FIGS. 4 to 7, the gap 101 between patterns 102 formed on a semiconductor substrate 100 is partially filled by depositing a first high density oxide film 104 on the semiconductor substrate 100. It is preferable to load a wafer into a high density plasma CVD apparatus shown in FIG. 7, transfer the wafer into a deposition chamber A, and then deposit the first high density oxide film 104 to a thickness sufficient to prevent generation of voids, for example between about 1000 Å μm to about 2000 Å μm, preferably using SiH₄, O₂, and Ar gases as plasma sources.

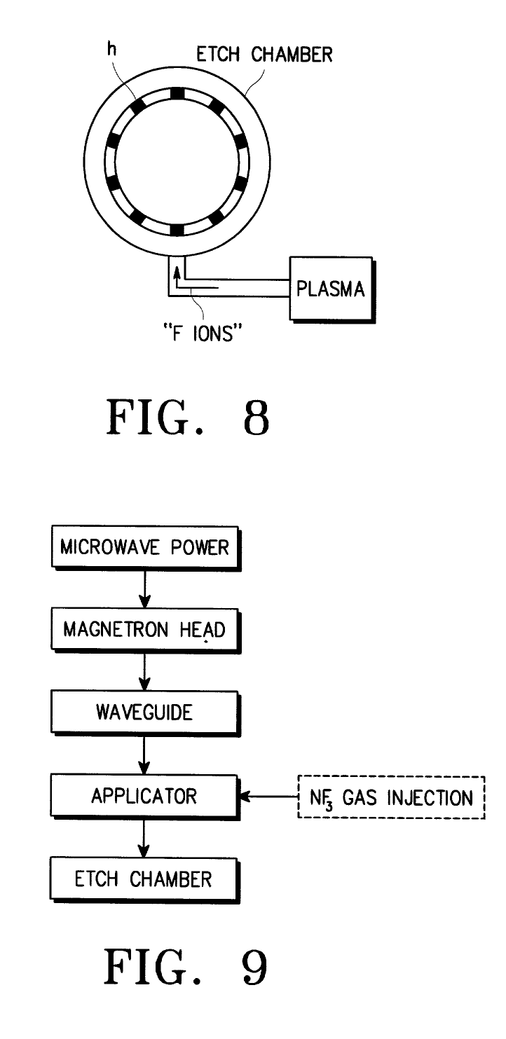

Referring to FIGS. 5 and 7, after the deposited wafer is moved from the deposition chamber A to an etch chamber, the first high density plasma oxide film 104 is etched to a predetermined depth, for example between about 100 Å μm to about 500 Å μm, isotropically using fluorine ions, thereby reducing the aspect ratio of the gap, for example to less than about 3.5:1. Preferably, the fluorine ions are produced in a remote plasma method and injected into the etch chamber through an annular pipe having a plurality of holes h to increase etch uniformity, as shown in FIG. 8. The structure of the etch chamber will now be described with reference to FIG. 9.

Referring to FIG. 9, a magnetron head, that has received current from a microwave power supply, generates microwaves. The microwaves reach an applicator through a circulator and a waveguide. NF₃ gas is injected into the applicator and a microwave plasma is formed by microwave power. Then, the NF₃ gas is resolved. Accordingly, fluorine ions ionized in the applicator are introduced into the etch chamber by pumping toward the etch chamber. The fluorine ions promote etching of an oxide film by chemical reaction in the etch chamber. Here, another fluorine-containing gas can be used instead of the NF₃ gas.

According to an embodiment of the present invention, a high density plasma oxide film is etched using fluorine ions formed in a remote plasma method, particularly a remote chemical plasma method, so that attacks into the etch chamber can be prevented and etch uniformity can be increased.

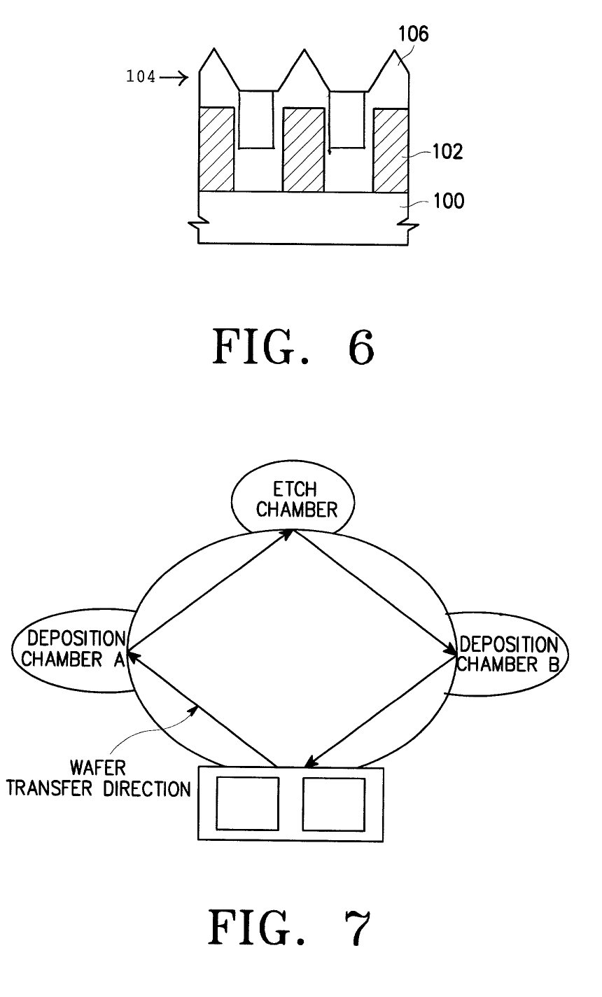

Referring to FIGS. 6 and 7, after the etched wafer is transferred from the etch chamber to a deposition chamber B, a second high density plasma oxide film 106 is deposited using SiH₄, O₂, and Ar gases as plasma sources, to thereby fill the gap between the patterns 102 without generating voids.

As described above, while the exemplary high density plasma CVD apparatus of the present invention includes a plurality of deposition chambers, in particular two deposition chambers, and one etch chamber to fill a gap by use of a high density plasma oxide film, deposition of a first high density plasma oxide film, isotropic etching using fluorine ions, and deposition of a second high density plasma oxide film can be sequentially implemented in the same chamber. However, the former case is more preferred in terms of process throughput because after one wafer is removed from the deposition chamber A to the etch chamber, another wafer can be loaded in the deposition chamber A for deposition.

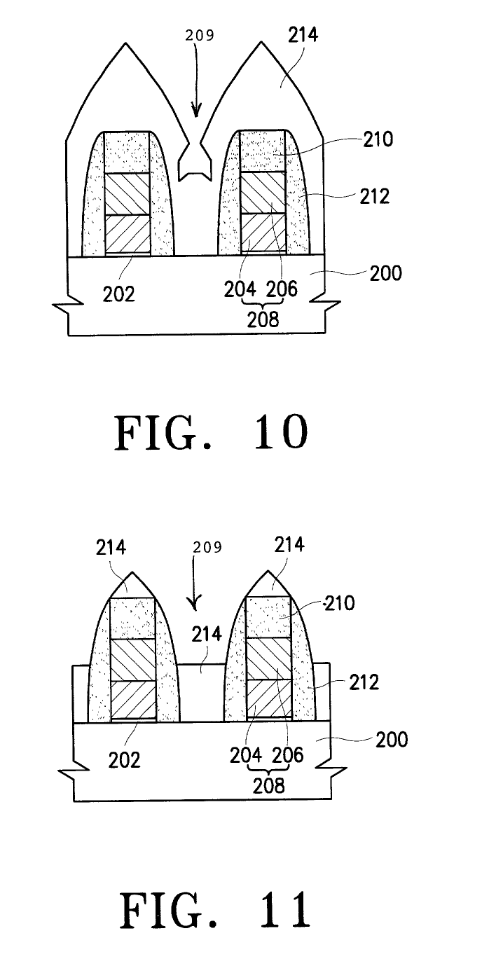

FIGS. 10 to 14 are sectional views illustrating a self-aligned contact forming process using the gap filling method of the present invention.

Referring to FIG. 10, a gate oxide film 202 is formed by thermal oxidation on a semiconductor substrate 200 having an active region and a field region defined thereon by a general device isolation process. A polysilicon layer 204, a tungsten silicide layer 206, and a nitride layer 210 are sequentially deposited on the gate oxide film 202 to thicknesses of about 1000, about 1500, and about 1800 Å. The polysilicon layer 204 is doped with a high concentration impurity in a general doping process such as a diffusion, ion implantation, or in-situ doping process. Other refractory metal silicides including titanium silicide or tantalum silicide can be used instead of the tungsten silicide.

Subsequently, the nitride layer 210 is patterned into a gate pattern by photolithography, and the tungsten silicide layer 206 and the polysilicon layer 204 are etched using the patterned nitride layer 210 as a mask. Thus, a polycide gate 208 is formed.

A nitride layer is deposited to a thickness of between about 500 to about 1000 Å on the resultant structure having the gate 208. Nitride layer spacers 212 are formed on the sidewalls of the nitride layer 210 and the gate 208 by etching back the overall surface of the nitride layer. Preferably, the nitride spacers 212 are about 800 Å in length. The nitride layer spacers 212 act as an etch stopping layer in a subsequent etching step for forming a self-aligned contact.

Thereafter, a source/drain region (not shown) is formed at both sides of the gate 208 by ion implantation using the nitride layer spacers 212 and the gate 208 as a mask. The gap 209 between gates 208 is partially filled by depositing a first high density plasma oxide film 214 on the resultant structure. Preferably, the first high density plasma oxide film 214 is deposited to a thickness sufficient to prevent generation of voids in the gap 209, as discussed above.

Referring to FIG. 11, the first high density plasma oxide film 214 is isotropically etched using fluorine ions that are produced in a remote plasma method. As a result, an oxide film redeposited on the sidewalls of the gate 208 during deposition of the first high density plasma oxide film 214 is etched and thus the upper opening between the gates 208 becomes wide.

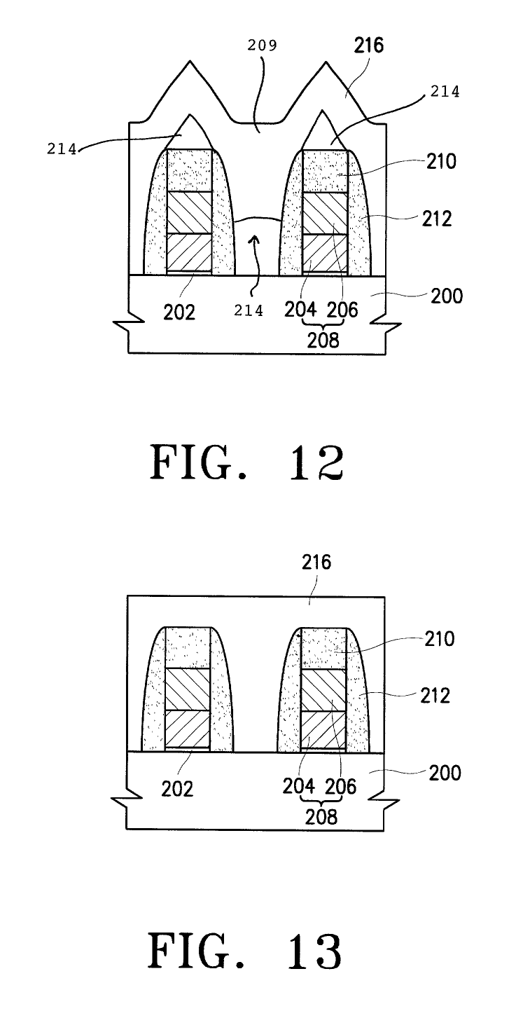

Referring to FIG. 12, the gap 209 between the gates 208 is completely filled by depositing a second high density plasma oxide film 216 on the resultant structure. The decrease of the aspect ratio of the gap by the etching step enables gap filling without generation of voids when the second high density plasma oxide film 216 is deposited.

Referring to FIG. 13, the surface of the substrate 200 is planarized by polishing the second high density plasma oxide film 216 to a predetermined depth by CMP (Chemical Mechanical Polishing).

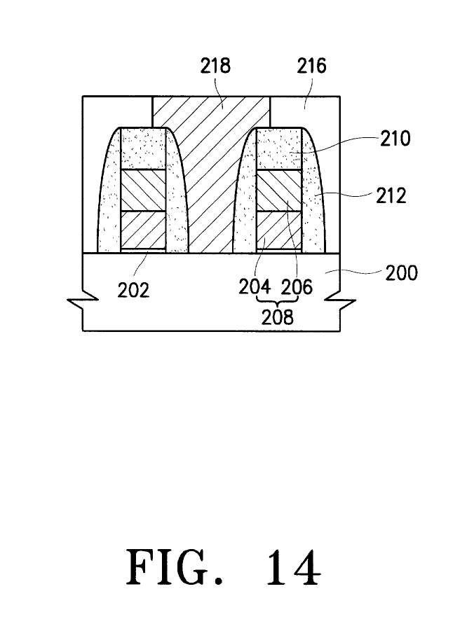

Referring to FIG. 14, a photoresist pattern (not shown) is formed on the second high density plasma oxide film 216 by photolithography to open a self-aligned contact area. Then, the second high density plasma oxide film 216 is etched using the photoresist pattern as a mask with a high nitride etch selectivity. As a result, a self-aligned contact hole is formed to expose the source/drain region of a transistor.

Subsequently, the photoresist pattern is stripped off, and a polysilicon layer is deposited on the resultant structure. The polysilicon layer is removed from the surface of the second high density plasma oxide film 216 by CMP, thereby forming a landing pad 218 having polysilicon filled in the self-aligned contact hole.

In accordance with an embodiment of the present invention as described above, the first high density plasma oxide film is deposited to a thickness sufficient to prevent generation of voids in the gap between fine patterns and in-situ etched using fluorine ions. Since an oxide film redeposited on the sidewalls of the patterns is etched, the upper opening between the patterns becomes wide and, as a result, the aspect ratio of the gap is reduced. The decrease of the gap aspect ratio leads to gap filling without generation of voids through deposition of the second high density plasma oxide film.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A method of fabricating a semiconductor device comprising the steps of:
(1) depositing a first high density plasma oxide film on a semiconductor substrate that has patterns with a gap formed thereon;
(2) etching the first high density plasma oxide film to a predetermined depth using fluorine ions; and
(3) depositing a second high density plasma oxide film on the resultant structure, thereby filling the gap between the patterns.

2. The method of fabricating a semiconductor device as claimed in claim 1, wherein steps (1), (2), and (3) are performed in situ.

3. The method of fabricating a semiconductor device as claimed in claim 1, wherein the first high density plasma oxide film is deposited to a thickness sufficient to prevent generation of voids in the gap in step (1).

4. The method of fabricating a semiconductor device as claimed in claim 3, wherein the first high density plasma oxide film is deposited to a thickness from about 1000 Å μm to about 2000 Å μm.

5. The method of fabricating a semiconductor device as claimed in claim 1, wherein the first high density plasma oxide film is deposited using SiH₄, O₂ and Ar in step (1).

6. The method of fabricating a semiconductor device as claimed in claim 1, wherein the first high density plasma oxide film is isotropically etched in step (2).

7. The method of fabricating a semiconductor device as claimed in claim 1, wherein the fluorine ions are formed in a remote plasma method in step (2).

8. The method of fabricating a semiconductor device as claimed in claim 7, wherein the fluorine ions are injected through an annular pipe having defined therein a plurality of holes.

9. The method of fabricating a semiconductor device as claimed in claim 1, wherein the second high density plasma oxide film is deposited using SiH₄, O₂ and Ar in step (3).

10. An apparatus for fabricating a semiconductor device comprising:
a deposition chamber for depositing an oxide film using high density plasma; and
an etch chamber adapted for etching the high density plasma oxide film using fluorine ions formed in a remote plasma method.

11. The apparatus for fabricating a semiconductor device as claimed in claim 10, further comprising an annular pipe having defined therein a plurality of holes for injecting the fluorine ions into the etch chamber.

12. The apparatus for fabricating a semiconductor device as claimed in claim 10, comprising a plurality of deposition chambers.

13. The apparatus for fabricating a semiconductor device as claimed in claim 12, comprising two deposition chambers.

14. The apparatus for fabricating a semiconductor device as claimed in claim 13, wherein the etch chamber is connected between the two deposition chambers.

15. A semiconductor device fabricated according to the method of claim 1.
